(19) United States
(12) Patent Application Publication
(10) Pub. No.: US 2019/0146293 A1
(43) Pub. Date: May 16, 2019

(54) ARRAY SUBSTRATE AND MANUFACTURING METHOD THEREOF, AND DISPLAY PANEL

(71) Applicants: BOE Technology Group Co., Ltd., Beijing (CN); Ordos Yuansheng Optoelectronics Co., Ltd., Inner Mongolia (CN)

(72) Inventors: Jinjin XUE, Beijing (CN); Dawei SHI, Beijing (CN); Haifeng XU, Beijing (CN); Lu YANG, Beijing (CN); Wentao WANG, Beijing (CN); Lei YAN, Beijing (CN); Lei YAO, Beijing (CN); Xiaowen SI, Beijing (CN); Fang YAN, Beijing (CN)

(21) Appl. No.: 16/110,190

(22) Filed: Aug. 23, 2018

(30) Foreign Application Priority Data
Nov. 14, 2017 (CN) 201711121403.1

(51) Int. Cl. G02F 1/1362; H01L 27/12; H01L 29/786; G02F 1/1368

(52) U.S. Cl. CPC G02F 1/136286; H01L 27/1244; H01L 27/1259; H01L 29/78633; H01L 29/78645; G02F 1/134363; G02F 1/1368; G02F 1/136209; G02F 2201/40; G02F 2001/13685; G02F 2001/136231; G02F 1/136227

(57) ABSTRACT

The present disclosure provides an array substrate which is divided into a plurality of pixel units. The array substrate includes a pixel electrode layer including a plurality of pixel electrodes; a data line layer including a plurality of data lines; and a metal electrode layer including a plurality of drain electrodes, each of the drain electrodes being electrically connected with one of the plurality of pixel electrodes, wherein the metal electrode layer and the data line layer are spaced apart from each other in the thickness direction of the array substrate. The present disclosure also provides a display panel and a manufacturing method of the array substrate.

### CROSS-REFERENCE TO RELATED APPLICATIONS

The present application claims the priority of Chinese Patent Application No. 201711121403.1, filed on Nov. 14, 2017, in the Chinese Intellectual Property Office, the contents of which are incorporated herein in their entirety by reference.

### TECHNICAL FIELD

The present disclosure relates to the field of display technology, and in particular, relates to an array substrate, a display panel including the array substrate, and a manufacturing method of the array substrate.

### BACKGROUND

With the requirement for high pixel per inch (PPI), wirings in an array substrate are becoming denser, which may cause defects such as short circuit, open circuit, and so on. When a defect such as short circuit or open circuit occurs in the array substrate, a display panel including the array substrate will have a dark spot when performing display.

### SUMMARY

As a first aspect of the present disclosure, there is provided an array substrate including: a pixel electrode layer including a plurality of pixel electrodes; a data line layer including a plurality of data lines; a metal electrode layer including a plurality of drain electrodes, each of which is electrically connected with one of the plurality of pixel electrodes, wherein the metal electrode layer and the data line layer are spaced apart from each other in a thickness direction of the array substrate.

According to an embodiment of the present disclosure, the array substrate further includes an insulating layer, and the data line layer and the metal electrode layer are at two opposite sides of the insulating layer in the thickness direction of the array substrate, respectively, wherein the metal electrode layer further includes a plurality of source electrodes, the number of which is the same as that of the drain electrodes. The array substrate is divided into a plurality of pixel units arranged in a plurality of rows and a plurality of columns, the pixel units in a same column sharing one data line, and the source electrodes of the pixel units in the same column being electrically connected with a corresponding data line through vias penetrating the insulating layer.

According to an embodiment of the present disclosure, the array substrate further includes a planarization layer covering the metal electrode layer, such that the pixel electrode layer and the metal electrode layer are at two opposite sides of the planarization layer in the thickness direction of the array substrate, respectively, wherein the pixel electrodes in the pixel electrode layer are electrically connected with corresponding drain electrodes through vias penetrating the planarization layer, respectively.

According to an embodiment of the present disclosure, the array substrate further includes an active layer, wherein the metal electrode layer further includes a plurality of gate electrodes, and each of the pixel units is provided with at least one of the plurality of gate electrodes therein; the insulating layer includes an interlayer insulating layer covering the data line layer and a gate insulating layer on a side of the interlayer insulating layer facing away from the data line layer; the active layer is between the interlayer insulating layer and the gate insulating layer; the metal electrode layer is on a side of the gate insulating layer facing away from the interlayer insulating layer; and each of the vias electrically connecting the source electrodes with the corresponding data line includes a first via portion and a second via portion which are formed as an integral structure, the first via portion penetrating the gate insulating layer, the second via portion penetrating the interlayer insulating layer, the first via portion being in contact with a corresponding portion of the active layer, and each of the drain electrodes being in contact with a corresponding portion of the active layer through a via penetrating the gate insulating layer.

According to an embodiment of the present disclosure, the array substrate further includes a light blocking layer including a plurality of light blocking members, and an orthographic projection of the light blocking members on the metal electrode layer overlaps with at least a portion of at least one of the gate electrodes, so as to prevent light from transmitting through the gate electrodes.

According to an embodiment of the present disclosure, the metal electrode layer includes a plurality of gate lines, a portion of which is formed to be the gate electrodes.

According to an embodiment of the present disclosure, the active layer includes a plurality of first portions and a second portion connected between the plurality of first portions, a length direction of the first portions being parallel to a length direction of the data lines, an orthographic projection of one of the plurality of first portions on the data line layer overlapping with a corresponding data line, and a portion of the gate line, an orthographic projection of which on the active layer overlaps with the first portion, being provided as the gate electrodes.

According to an embodiment of the present disclosure, the array substrate further includes a passivation layer and a common electrode layer, the passivation layer covering the pixel electrode layer, the common electrode layer being on a side of the passivation layer facing away from the pixel electrode layer, and the common electrode layer including a plurality of common electrodes.

As a second aspect of the present disclosure, there is provided a display panel including an array substrate which is the above array substrate provided by the present disclosure.

As a third aspect of the present disclosure, there is provided a manufacturing method of an array substrate, the manufacturing method including:

forming a data line layer including a plurality of data lines;

forming a metal electrode layer including a plurality of drain electrodes, the metal electrode layer and the data line layer being spaced apart from each other in a thickness direction of the array substrate;

forming a pixel electrode layer including a plurality of pixel electrodes, each of the drain electrodes being connected with one of the plurality of pixel electrodes electrically.

According to an embodiment of the present disclosure, the metal electrode layer further includes a plurality of source electrodes, the number of which is the same as that of the drain electrodes, the array substrate is divided into a plurality of pixel units arranged in a plurality of rows and a plurality of columns, and the pixel units in a same column share one data line, the manufacturing method further including:

forming an insulating layer, such that the data line layer and the metal electrode layer are at two opposite sides of the insulating layer in the thickness direction of the array substrate, respectively, wherein the source electrodes of the pixel units in the same column are electrically connected with a corresponding data line through vias penetrating the insulating layer, respectively.

According to an embodiment of the present disclosure, the manufacturing method further includes: forming a planarization layer to cover the metal electrode layer, such that the pixel electrode layer and the metal electrode layer are at two opposite sides of the planarization layer in the thickness direction of the array substrate, respectively; and connecting the pixel electrodes in the pixel electrode layer electrically to corresponding drain electrodes through vias penetrating the planarization layer, respectively.

According to an embodiment of the present disclosure, the metal electrode layer further includes a plurality of gate electrodes, each of the pixel units being provided with at least one of the plurality of gate electrodes therein, and the insulating layer includes an interlayer insulating layer and a gate insulating layer, the manufacturing method further including:

forming an active layer between forming the interlayer insulating layer and forming the gate insulating layer,

forming a first via portion and a second via portion integrally, the first via portion penetrating the gate insulating layer, the second via portion penetrating the interlayer insulating layer, and the first via portion being in contact with a corresponding portion of the active layer, and

forming a third via, the third via penetrating the gate insulating layer, and each of the drain electrodes being in contact with a corresponding portion of the active layer through the third via.

According to an embodiment of the present disclosure, the manufacturing method further includes:

forming a light blocking layer, wherein the light blocking layer includes a plurality of light blocking members, and an orthographic projection of the light blocking members on the metal electrode layer overlaps with at least a portion of at least one of the gate electrodes, so as to prevent light from transmitting through the gate electrodes.

### BRIEF DESCRIPTION OF THE DRAWINGS

The accompanying drawings, which constitute a part of the specification, are provided for further understanding of the present disclosure, and for explaining the present disclosure along with the following specific implementations, but not intended to limit the present disclosure, in which:

FIG. 1 is a partial cross-sectional view of an array substrate in the related art;

FIG. 2 is a partial cross-sectional view of an array substrate provided by the present disclosure;

FIG. 3 is a partial top view of an array substrate provided by the present disclosure; and

FIG. 4 is a flowchart of a manufacturing method of an array substrate provided by the present disclosure.

### DETAILED DESCRIPTION

The specific implementations of the present disclosure will be described in detail below in conjunction with the drawings. It should be understood that specific implementations to be described herein are merely used for illustrating and interpreting the present disclosure and not for limiting the present disclosure.

As shown in FIG. 1, in the related art, an array substrate of a display device includes thin film transistors, each of which includes a source electrode 110 and a drain electrode 120. The source electrode 110, the drain electrode 120 and data lines are disposed in the same layer, and a pixel electrode 210 is electrically connected with the drain electrode 120. However, with the requirement for high PPI, wirings in an array substrate are becoming denser, which may cause defects such as short circuit, open circuit, and so on. When a defect such as short circuit or open circuit occurs in the array substrate, a display panel including the array substrate will have a dark spot when performing display.

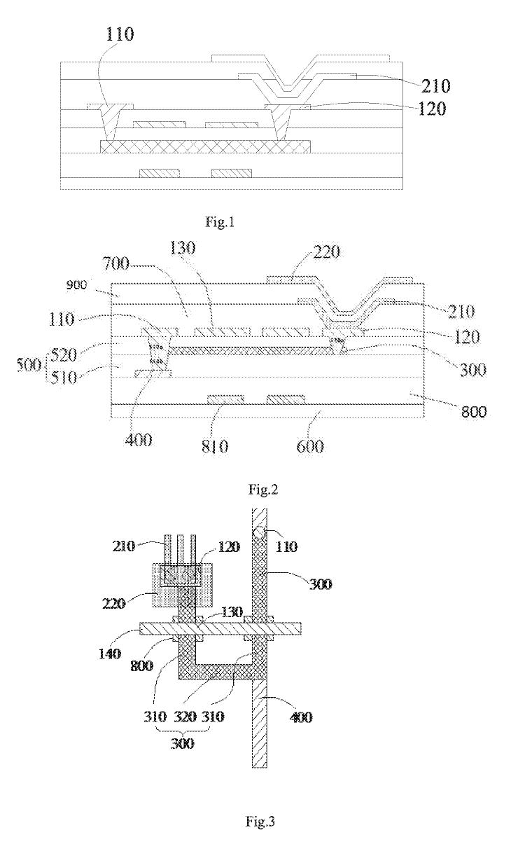

Accordingly, as an aspect of the present disclosure, there is provided an array substrate, which is divided into a plurality of pixel units and includes a pixel electrode layer and a data line layer, as shown in FIG. 2. The pixel electrode layer includes a plurality of pixel electrodes 210, and each of the pixel units is provided with one of the plurality of pixel electrodes 210 therein. The data line layer includes a plurality of data lines 400. The array substrate further includes a metal electrode layer including a plurality of drain electrodes 120, each of the plurality of drain electrodes 120 being electrically connected with one of the pixel electrodes. The orthographic projection of the drain electrode on the pixel electrode layer may at least partially overlap with the pixel electrode. The metal electrode layer and the data line layer are spaced apart from each other in a thickness direction of the array substrate.

In the present disclosure, since the metal electrode layer and the data line layer are not in the same layer, the area of the drain electrode in the metal electrode layer can be increased, thereby increasing the overlapping area of the drain electrode with the pixel electrode, and increasing an aperture ratio. In addition, the short circuit of the drain electrode of the metal electrode layer and the data line corresponding to an adjacent column of the pixel units is avoided. It can be seen that the pixel electrode provided by the present disclosure is easier to manufacture and the yield of the array substrate can be improved.

With the improvement of the yield of the array substrate, the dark spot defects in the display panel are reduced accordingly.

In the present disclosure, there is no particular requirement on how to electrically connect the drain electrode with the pixel electrode. For example, the drain electrode may be in direct contact with the pixel electrode and electrically connected with the pixel electrode. In an embodiment shown in FIG. 2, the array substrate includes a planarization layer 700 covering the metal electrode layer, and the pixel electrode layer is disposed on the planarization layer 700, such that the pixel electrode layer and the metal electrode layer are disposed on two opposite sides of the planarization layer 700 in a thickness direction of the array substrate, respectively. The pixel electrode 210 is electrically connected with a corresponding drain electrode 120 through a via penetrating the planarization layer 700.

As described above, the drain electrode 120 and the data line 400 are disposed in different layers, and therefore, the density of the conductive pattern is relatively low in the metal electrode layer, so that the drain electrode 120 can be set to have a large surface area. In other words, as compared to the array substrate shown in FIG. 1, in the case of the same PPI, the surface area of the drain electrode 120 in the array substrate provided by the present disclosure can be larger. Since the drain electrode 120 has a larger area, the accuracy requirement for the via connecting the drain electrode 120 with the pixel electrode 210 is lowered, so that the orthographic projection of the via on the metal electrode layer can be completely fallen in the area of the drain electrode 120, that is, there is no misalignment for the via, and the portion of the via electrically connected with the drain electrode 120 does not have a shape of step, thereby ensuring that a transparent electrode film disposed in the via does not break. It can be seen that the array substrate provided by the present disclosure is easier to achieve high PPI.

As a specific implementation, the pixel units are arranged in a plurality of rows and a plurality of columns, and each column of pixel units corresponds to one data line 400. As shown in FIG. 2, the array substrate includes an insulating layer 500, and the data line layer and the metal electrode layer are disposed on two opposite sides of the insulating layer 500 in the thickness direction of the array substrate, respectively.

In the present disclosure, there is no particular limit on how to set the source electrode. In order to reduce the number of steps of the mask process, according to an embodiment of the present disclosure and as shown in FIG. 2, the metal electrode layer further includes a plurality of source electrodes 110. The number of the source electrodes 110 is the same as that of the drain electrodes 120. The source electrodes 110 of the pixel units in the same column are electrically connected with a corresponding data line through vias penetrating the insulating layer 500, respectively.

In order to further reduce the number of steps of the mask process, according to an embodiment of the present disclosure and as shown in FIG. 2, the metal electrode layer further includes a plurality of gate electrodes 130, and each of the pixel units is provided with at least one of the plurality of gate electrodes 130 therein.

It will be easily understood by those skilled in the art that each array substrate includes a plurality of thin film transistors. A source electrode, a drain electrode, a gate electrode, and an active layer in one pixel unit constitute a thin film transistor. In the present disclosure, there is no particular limit to the structure of the thin film transistor in the pixel unit. For example, the thin film transistor may have a top gate structure, or may have a bottom gate structure. In the embodiment shown in FIG. 2, the thin film transistor has a top gate structure. Specifically, the array substrate includes an active layer 300 which is provided in each of the pixel units. The insulating layer 500 includes an interlayer insulating layer 510 and a gate insulating layer 520, and the interlayer insulating layer 510 covers the data line layer. The active layer 300 is disposed between the interlayer insulating layer 510 and the gate insulating layer 520.

The gate insulating layer 520 is disposed on a side of the interlayer insulating layer 510 facing away from the data line layer. The metal electrode layer is disposed on a side of the gate insulating layer 520 facing away from the interlayer insulating layer 510. The via connecting the source electrode 110 and the data line 400 corresponding to the source electrode 110 includes a first via portion 110a and a second via portion 110b which are formed as an integral structure, the first via portion 110a penetrating the gate insulating layer 520, the second via portion 110b penetrating the interlayer insulating layer 510, and the first via portion 110a being in contact with the active layer 300. A via 120c connecting the drain electrode 120 to the active layer 300 penetrates the gate insulating layer 520.

The array substrate is applied to a display device. As an embodiment, the array substrate is applied to a liquid crystal display device. Therefore, a backlight source can be disposed on the light incident side of the array substrate. In order to prevent the active layer of the thin film transistor from aging under illumination for a long time, according to an embodiment of the present disclosure, the array substrate may include a light blocking layer 800 including a plurality of light blocking members 810. As shown in FIG. 2, the light blocking layer 800 is disposed on the light incident side of the gate electrode 130 (for example, in the situation shown in FIG. 2, the light blocking layer 800 is disposed on a side of the gate electrode 130 facing away from the planarization layer 700), and the position of the light blocking member 810 corresponds to the gate electrode 130 to prevent light from transmitting through the gate electrode 130. Since a channel is formed at a position in the active layer 300 corresponding to the gate electrode 130 after the gate electrode 130 is applied with power, the light blocking member 810 provided at the position corresponding to the gate electrode 130 can effectively prevent the channel from aging. The position of the light blocking member 810 corresponding to the gate electrode 130 described herein means that the orthographic projection of the light blocking member 810 on the metal electrode layer at least partially overlaps with the gate electrode 130. According to an embodiment of the present disclosure, the orthographic projection of the light blocking member 810 on the metal electrode layer completely overlaps with the gate electrode 130.

In order to simplify a mask forming a pattern in the metal electrode layer, according to an embodiment of the present disclosure, the metal electrode layer includes a plurality of gate lines, a portion of which is formed to be the gate electrodes.

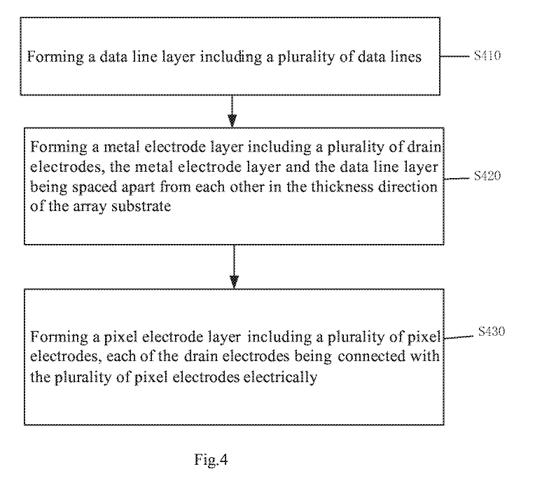

The thin film transistor may have a single gate structure (i.e., one thin film transistor includes one gate electrode) or may have a double gate structure (i.e., one thin film transistor includes two gate electrodes). The thin film transistor having a double gate structure has good switching performance, and in the array substrate shown in FIGS. 2 and 3, the thin film transistor has a double gate structure.

In the present disclosure, the thin film transistor having a double gate structure may be implemented by arranging the structure of an active layer. In the embodiment shown in FIG. 3, the active layer 300 includes two first portions 310 and a second portion 320 connected between the two first portions 310. As shown in FIG. 3, the length direction of the first portion 310 is parallel with that of the data lines 400, with the orthographic projection of one of the first portions 310 on the data line layer overlapping with the corresponding data line 400, and the orthographic projection of the other first portion 310 on the data line layer being spaced from the corresponding data line 400.

As shown in FIG. 3, a portion of the gate line 140 whose orthographic projection on the metal electrode layer overlaps with the first portion 310 is formed as the gate electrode 130.

In the embodiment shown in FIG. 2, the array substrate further includes a passivation layer 900 and a common electrode layer, and the pixel electrode layer and the common electrode layer are sequentially stacked in the thickness direction of the array substrate. As shown in the figure, the common electrode layer includes a common electrode 220. The common electrode 220 and the pixel electrode 210 both are made of a transparent electrode material.

As shown in FIG. 2, the array substrate further includes a base substrate 600. In order to prevent impurities in the base substrate 600 from diffusing into the thin film transistor, a buffer layer may be disposed on the base substrate 600 according to an embodiment of the present disclosure.

As a second aspect of the present disclosure, there is provided a display panel including an array substrate, wherein the array substrate is the above-described array substrate provided by the present disclosure. As described above, the array substrate has a high yield, and therefore, the display panel also has a high yield.

As a specific embodiment, the display panel is a liquid crystal display panel. Therefore, the display panel further includes a counter substrate arranged opposite to and aligned with the array substrate and a liquid crystal material layer which is disposed between the array substrate and the counter substrate.

As a third aspect of the present disclosure, there is provided a manufacturing method of an array substrate, and as shown in FIG. 4, the manufacturing method includes steps S410 to S430.

At Step S410, a data line layer including a plurality of data lines is formed.

At Step S420, a metal electrode layer including a plurality of drain electrodes is formed, the metal electrode layer and the data line layer being spaced apart from each other in the thickness direction of the array substrate.

At Step S430, a pixel electrode layer including a plurality of pixel electrodes is formed, each of the drain electrodes being connected with one of the plurality of pixel electrodes electrically.

According to an embodiment of the present disclosure, the metal electrode layer further includes a plurality of source electrodes, the number of which is the same as that of the drain electrodes, the array substrate is divided into a plurality of pixel units, the plurality of pixel units are arranged in a plurality of rows and a plurality of columns, and the pixel units in the same column share one data line, the manufacturing method further including:

forming an insulating layer on the data line layer,

wherein the source electrodes in the same column of pixel units are electrically connected with a corresponding data line through a via penetrating the insulating layer.

According to an embodiment of the present disclosure, the manufacturing method further includes: forming a planarization layer on the metal electrode layer, and connecting the pixel electrodes in the pixel electrode layer electrically to the corresponding drain electrodes through vias penetrating the planarization layer, respectively.

According to an embodiment of the present disclosure, the metal electrode layer further includes a plurality of gate electrodes, each of the pixel units is provided with at least one of the plurality of gate electrodes therein, and the insulating layer includes an interlayer insulating layer and a gate insulating layer, the manufacturing method further including:

forming an active layer between forming the interlayer insulating layer and forming the gate insulating layer,

forming a first via portion and a second via portion integrally, the first via portion penetrating the gate insulating layer, the second via portion penetrating the interlayer insulating layer, the first via portion being in contact with a corresponding portion of the active layer, and

forming a third via, the third via penetrating the gate insulating layer, and each of the drain electrodes being in contact with a corresponding portion of the active layer through the third via.

According to an embodiment of the present disclosure, the manufacturing method further includes:

forming a light blocking layer, wherein the light blocking layer includes a plurality of light blocking members, and the orthographic projection of the light blocking member on the metal electrode layer overlaps with at least a portion of at least one of the gate electrodes, so as to prevent light from transmitting through the gate electrodes.

As such, the array substrate produced by the above manufacturing method has a high yield.

It should be understood that, the above embodiments are only exemplary embodiments for the purpose of explaining the principle of the present disclosure, and the present disclosure is not limited thereto. For one of ordinary skill in the art, various improvements and modifications may be made without departing from the spirit and essence of the present disclosure. These improvements and modifications also fall within the protection scope of the present disclosure.

What is claimed is:

1. An array substrate, comprising:
a pixel electrode layer comprising a plurality of pixel electrodes;
a data line layer comprising a plurality of data lines;
a metal electrode layer comprising a plurality of drain electrodes, each of which is electrically connected with one of the plurality pixel electrodes,
wherein the metal electrode layer and the data line layer are spaced apart from each other in a thickness direction of the array substrate.

2. The array substrate according to claim 1, further comprising an insulating layer, wherein
the data line layer and the metal electrode layer are at two opposite sides of the insulating layer in the thickness direction of the array substrate, respectively,
the metal electrode layer further comprises a plurality of source electrodes, the number of which is the same as that of the drain electrodes, and
the array substrate is divided into a plurality of pixel units arranged in a plurality of rows and a plurality of columns, the pixel units in a same column sharing one data line, and the source electrodes of the pixel units in the same column being electrically connected with a corresponding data line through vias penetrating the insulating layer.

3. The array substrate according to claim 1, further comprising a planarization layer covering the metal electrode layer, such that the pixel electrode layer and the metal electrode layer are at two opposite sides of the planarization layer in the thickness direction of the array substrate, respectively,
wherein the pixel electrodes in the pixel electrode layer are electrically connected with corresponding drain electrodes through vias penetrating the planarization layer, respectively.

4. The array substrate according to claim 2, further comprising an active layer, wherein
the metal electrode layer further comprises a plurality of gate electrodes, and each of the pixel units is provided with at least one of the plurality of gate electrodes therein,
the insulating layer comprises an interlayer insulating layer covering the data line layer and a gate insulating layer on a side of the interlayer insulating layer facing away from the data line layer, the active layer being between the interlayer insulating layer and the gate insulating layer, and the metal electrode layer being on a side of the gate insulating layer facing away from the interlayer insulating layer, and
each of the vias electrically connecting the source electrodes with the corresponding data line comprises a first via portion and a second via portion which are formed as an integral structure, the first via portion penetrating the gate insulating layer, the second via portion penetrating the interlayer insulating layer, the first via portion being in contact with a corresponding active layer, and each of the drain electrodes being in contact with a corresponding portion of the active layer through a via penetrating the gate insulating layer.

5. The array substrate according to claim 4, further comprising a light blocking layer which comprises a plurality of light blocking members, wherein an orthographic projection of the light blocking members on the metal electrode layer overlaps with at least a portion of at least one of the gate electrodes, so as to prevent light from transmitting through the gate electrodes.

6. The array substrate according to claim 4, wherein the metal electrode layer comprises a plurality of gate lines, a portion of which is formed to be the gate electrodes.

7. The array substrate according to claim 6, wherein the active layer comprises a plurality of first portions and a second portion connected between the plurality of first portions, a length direction of the plurality of first portions being parallel to a length direction of the data lines, an orthographic projection of one of the plurality of first portions on the data line layer overlapping with a corresponding data line, and a portion of the gate line, an orthographic projection of which on the active layer overlaps with the plurality of first portions, being provided as the gate electrodes.

8. The array substrate according to claim 1, further comprising a passivation layer and a common electrode layer, the passivation layer covering the pixel electrode layer, the common electrode layer being on a side of the passivation layer facing away from the pixel electrode layer, and the common electrode layer comprising a plurality of common electrodes.

9. A display panel, comprising an array substrate, wherein the array substrate is the array substrate according to claim 1.

10. A manufacturing method of an array substrate, comprising:
forming a data line layer comprising a plurality of data lines;
forming a metal electrode layer comprising a plurality of drain electrodes, the metal electrode layer and the data line layer being spaced apart from each other in a thickness direction of the array substrate;
forming a pixel electrode layer comprising a plurality of pixel electrodes, each of the drain electrodes being connected with one of the plurality of pixel electrodes electrically.

11. The manufacturing method according to claim 10, wherein the metal electrode layer further comprises a plurality of source electrodes, the number of which is the same as that of the drain electrodes, the array substrate is divided into a plurality of pixel units arranged in a plurality of rows and a plurality of columns, and the pixel units in a same column share one data line, the manufacturing method further comprising:
forming an insulating layer, such that the data line layer and the metal electrode layer are at two opposite sides of the insulating layer in the thickness direction of the array substrate, respectively,
wherein the source electrodes of the pixel units in the same column are electrically connected with a corresponding data line through vias penetrating the insulating layer, respectively.

12. The manufacturing method according to claim 10, further comprising:
forming a planarization layer to cover the metal electrode layer, such that the pixel electrode layer and the metal electrode layer are at two opposite sides of the planarization layer in the thickness direction of the array substrate, respectively; and
connecting the pixel electrodes in the pixel electrode layer electrically to corresponding drain electrodes through vias penetrating the planarization layer, respectively.

13. The manufacturing method according to claim 10, wherein the metal electrode layer further comprises a plurality of gate electrodes, each of the pixel units being provided with at least one of the plurality of gate electrodes therein, and the insulating layer comprises an interlayer insulating layer and a gate insulating layer, the manufacturing method further comprising:
forming an active layer between forming the interlayer insulating layer and forming the gate insulating layer,
forming a first via portion and a second via portion integrally, the first via portion penetrating the gate insulating layer, the second via portion penetrating the interlayer insulating layer, and the first via portion being in contact with a corresponding portion of the active layer, and
forming a third via, the third via penetrating the gate insulating layer, and each of the drain electrodes being in contact with a corresponding portion of the active layer through the third via.

14. The manufacturing method according to claim 13, further comprising:
forming a light blocking layer, wherein the light blocking layer comprises a plurality of light blocking members, and an orthographic projection of the light blocking members on the metal electrode layer overlaps with at least a portion of at least one of the gate electrodes, so as to prevent light from transmitting through the gate electrodes.
